(19) United States
(12) Patent Application Publication
(10) Pub. No.: US 2025/0167169 A1
(43) Pub. Date: May 22, 2025

(54) METHOD OF PACKAGING CHIP, CHIP PACKAGING STRUCTURE, AND TERMINAL DEVICE

(71) Applicants: HongQiSheng Precision Electronics (QinHuangDao) Co., Ltd., Qinhuangdao (CN); Avary Holding (Shenzhen) Co., Limited., Shenzhen (CN); GARUDA TECHNOLOGY CO., LTD., New Taipei (TW)

(72) Inventor: ZHI-YONG HUANG, Shenzhen (CN)

(21) Appl. No.: 18/959,999

(22) Filed: Nov. 26, 2024

Related U.S. Application Data
(63) Continuation-in-part of application No. PCT/CN2023/132975, filed on Nov. 21, 2023.

(51) Int. Cl. H01L 23/00; H01L 21/48; H01L 23/13; H01L 23/31; H01L 23/498

(52) U.S. Cl. CPC H01L 24/81; H01L 21/4857; H01L 23/13; H01L 24/16; H01L 23/3107; H01L 23/49822; H01L 2224/10135; H01L 2224/16157; H01L 2224/81002; H01L 2224/81048; H01L 2224/81097; H01L 2224/81935

(57) ABSTRACT

A method of packaging a chip includes: forming a groove on a circuit board. Providing a chip assembly, the chip assembly includes the chip, conductive pastes, and a deformable member. Placing the chip assembly at a first temperature to cause the deformable member to contract. Placing the chip assembly in the groove; heating the chip assembly at a second temperature. Subjecting the circuit board and the chip assembly to reflow soldering at a third temperature. The third temperature is greater than the second temperature, and the second temperature is greater than the first temperature. The present disclosure further provides a chip packaging structure and a terminal device.

### FIELD

The subject matter herein generally relates to chip packaging, and more particularly, to a method of packaging a chip, a chip packaging structure, and a terminal device.

### BACKGROUND

During a chip packaging process, holes are drilled on a circuit board, and metal is plated in the holes to form via holes. The via holes can electrical connect the circuit board to a chip. If solder pads are densely distributed on the chip, high precision is required for both the drilling and plating processes, otherwise poor soldering may occur. Therefore, there is a room for improvement in the art.

### BRIEF DESCRIPTION OF THE DRAWINGS

Implementations of the present technology will now be described, by way of example only, with reference to the attached figures.

FIG. 1 is a cross-sectional view of a circuit board wherein a groove is formed on the circuit board in a chip packaging process according to an embodiment of the present disclosure.

FIG. 2 is a cross-sectional view of a chip assembly wherein the chip assembly is placed at a first temperature to cause a deformable member of the chip assembly to contract in the chip packaging process according to an embodiment of the present disclosure.

FIG. 3 is a cross-sectional view showing the chip assembly of FIG. 2 placed in the groove of FIG. 1.

FIG. 4 is a cross-sectional view showing the circuit board and the chip assembly of FIG. 3 placed at a second temperature to cause the deformable member to recover to an original size of the deformable member.

FIG. 5 is a cross-sectional view showing the circuit board and the chip assembly of FIG. 4 placed at a third temperature for reflow soldering.

FIG. 6 is a cross-sectional view showing the circuit board and the chip assembly of FIG. 5, after being placed in the second temperature.

FIG. 7 is a cross-sectional view showing an encapsulating layer formed on the groove and a surface of the circuit board shown in FIG. 6.

FIG. 8 is a cross-sectional view showing a copper-clad laminate placed on a surface of the encapsulating layer and the circuit board shown in FIG. 7.

FIG. 9 is a cross-sectional view showing a through hole formed on the circuit board shown in FIG. 8.

FIG. 10 is a diagrammatic view of a chip packaging structure obtained after forming a conductive layer in the through hole of FIG. 9 and performing circuit patterning on the copper-clad laminate.

FIG. 11 is a diagrammatic view of a portion of the chip packaging structure shown in FIG. 10.

FIG. 12 is a flowchart of an embodiment of a method of packaging a chip according to the present disclosure.

FIG. 13 is a diagrammatic view of a terminal device according to an embodiment according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

Some embodiments of the present disclosure will be described in detail with reference to the drawings. If no conflict, the following embodiments and features in the embodiments can be combined with each other.

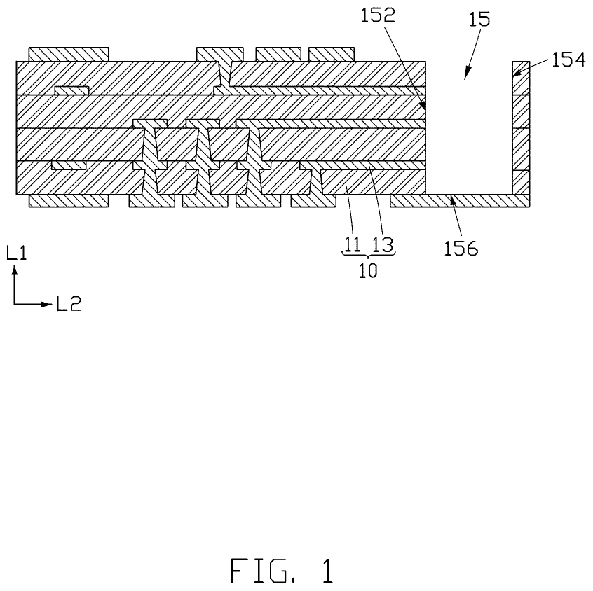

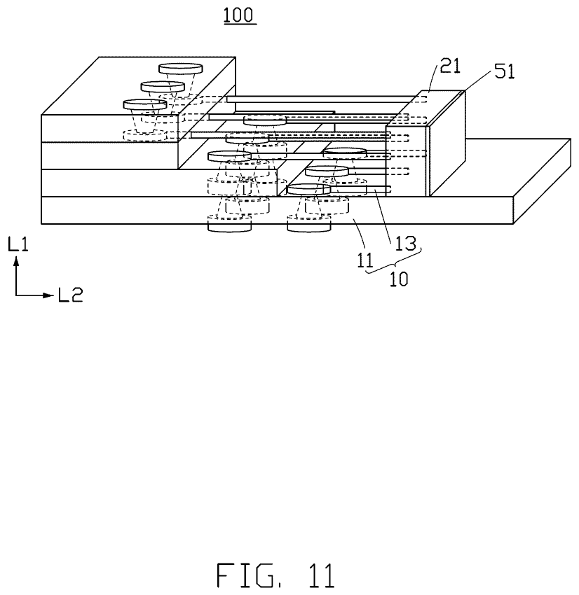

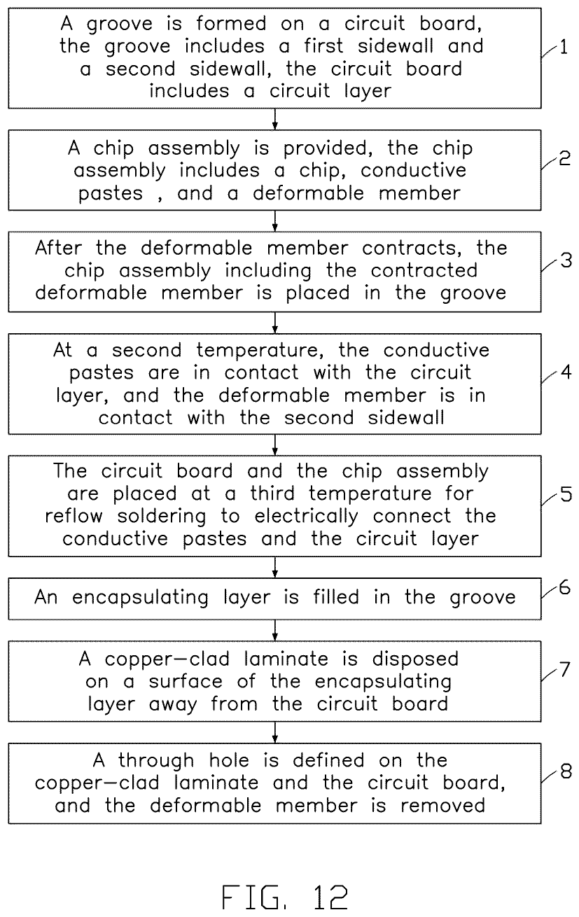

Referring to FIGS. 1-12, a method of packaging a chip is provided according to an embodiment of the present disclosure. The method is provided by way of example, as there are a variety of ways to carry out the method. Referring to FIG. 12, the method can begin at block 1.

In block 1, referring to FIG. 1, a groove 15 is formed on a circuit board 10. The groove 15 includes a first sidewall 152 and a second sidewall 154 opposite to each other. The circuit board 10 includes a circuit layer 13, and the circuit layer 13 is exposed from the first sidewall 152.

The circuit board 10 can be a flexible board, a rigid board, or a flexible-rigid board. The circuit board 10 can further include a dielectric layer 11, and the circuit layer 13 and the dielectric layer 11 are stacked along a first direction L1. The circuit board 10 can include one circuit layer 13 or a plurality of circuit layers 13. In the embodiment, the circuit board 10 includes a plurality of circuit layers 13.

The groove 15 is recessed along the first direction L1. The groove 15 further includes a bottom wall 156 connected to the first sidewall 152 and the second sidewall 154. The first sidewall 152, the second sidewall 154, and the bottom wall 156 cooperative define the groove 15. In the embodiment, the first sidewall 152 and the second direction L2 are both parallel to the first direction L1, and the bottom wall 156 is parallel to the second direction L2. The second direction L2 can be perpendicular to the first direction L1

The groove 15 can be formed by laser cutting or mechanical drilling.

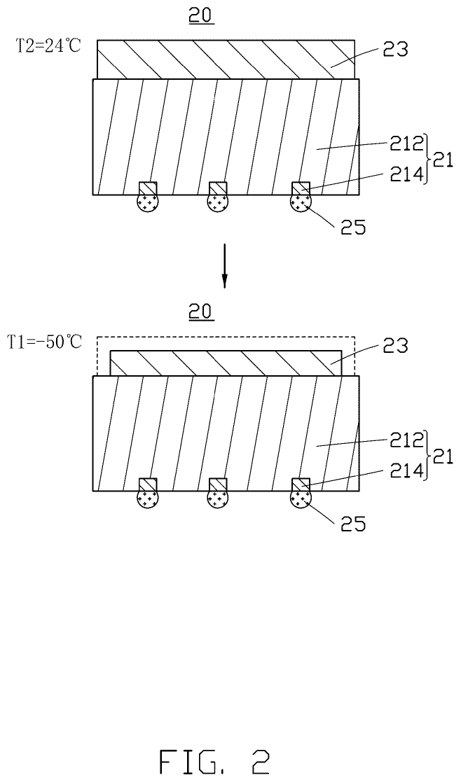

In block 2, referring to FIG. 2, a chip assembly 20 is provided. The chip assembly 20 includes a chip 21, conductive pastes 25, and a deformable member 23. The deformable member 23 and the conductive pastes 25 are disposed on opposite surfaces of the chip 21. The chip assembly 20 is placed at a first temperature T1 to cause the deformable member 23 to contract.

The chip 21 includes a body 212 and a plurality of solder pads 214. The solder pads 214 are disposed on a surface of the body 212. The deformable member 23 is disposed on a surface of the body 212 opposite to the solder pads 214, and the conductive pastes 25 are disposed on a surface of each solder pad 214. The circuit layer 13 that is exposed from the groove 15 corresponds to the conductive pastes 25. That is, the groove 15 is recessed along the first direction L1, while the conductive pastes 25, the chip 21, and the deformable member 23 are disposed along the second direction L2, and the first direction L1 and the second direction L2 are perpendicular to each other.

The conductive pastes 25 can be made of tin paste, silver paste, etc.

A thermal expansion coefficient of the deformable member 23 is greater than a thermal expansion coefficient of the circuit board 10, thereby ensuring that an expansion amplitude of the deformable member 23 is greater than an expansion amplitude of the circuit board 10 under high-temperature environments. A material of the deformable member 23 can be selected from one of zinc, copper, lead, and aluminum. In the embodiment, the deformable member 23 is made of zinc, and the thermal expansion coefficient of zinc is 3.6×10⁻⁵K⁻¹.

In the embodiment, the chip assembly 20 is cooled from a second temperature T2 to the first temperature T1, and the second temperature T2 is greater than the first temperature T1. The second temperature T2 can be a room temperature, such as 15 Celsius to 35 Celsius, which is constant that does not change without external influence. When the chip assembly 20 is at the first temperature T1, the deformable member 23 contracts at the second temperature T2, and a volume of the deformable member 23 decreases. The first temperature T1 can be less than or equal to 0 degrees, such as −25 degrees, −40 degrees, −50 degrees, etc. In the embodiment, the chip assembly 20 is placed at low temperature of −50 Celsius to contract the deformable member 23. The chip 21 can be made of silicon, and a thermal expansion coefficient of silicon is 2.4×10⁻⁶K⁻¹, which is smaller than the thermal expansion coefficient of the deformable member 23. A contraction amount of the chip 21 at the first temperature T1 can be omitted.

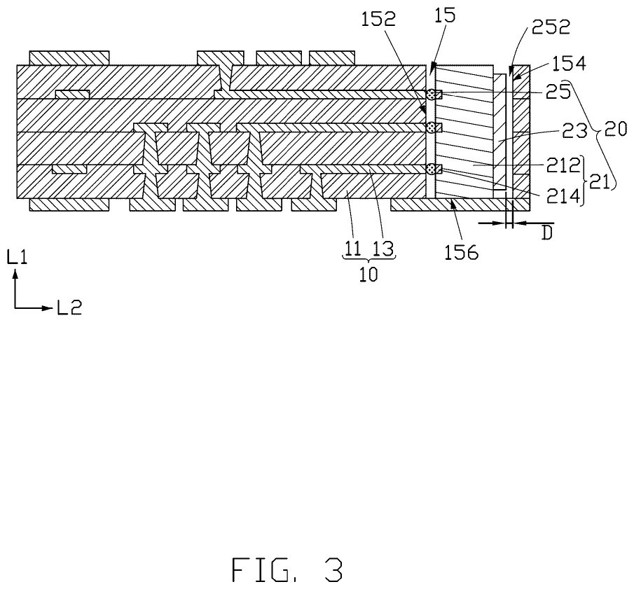

In block 3, referring to FIG. 3, after the deformable member 23 contracts, the chip assembly 20 including the contracted deformable member 23 is placed in the groove 15. The deformable member 23 can be spaced apart from the second sidewall 154, a first gap 252 is formed between the deformable member 23 and the second sidewall 154.

After the chip assembly 20 has been placed at the first temperature T1 for a time period, the chip assembly 20 is placed in the groove 15, with the conductive pastes 25 facing the first sidewall 152, and the deformable member 23 facing the second sidewall 154. Along the second direction L2, a width of the chip assembly 20 is less than a width of the groove 15. Therefore, after the chip assembly 20 with the deformable member 23 being contracted is placed in the groove 15, a distance D is maintained between the deformable member 23 and the second sidewall 154, thereby allowing the chip assembly 20 to adjust its position within the groove 15, so that the conductive pastes 25 can correspond to the circuit layer 13.

In some embodiments, the distance D between the deformable member 23 and the second sidewall 154 is greater than or equal to 0.56 um, to facilitate the adjustment of the position of the chip assembly 20 within the groove 15.

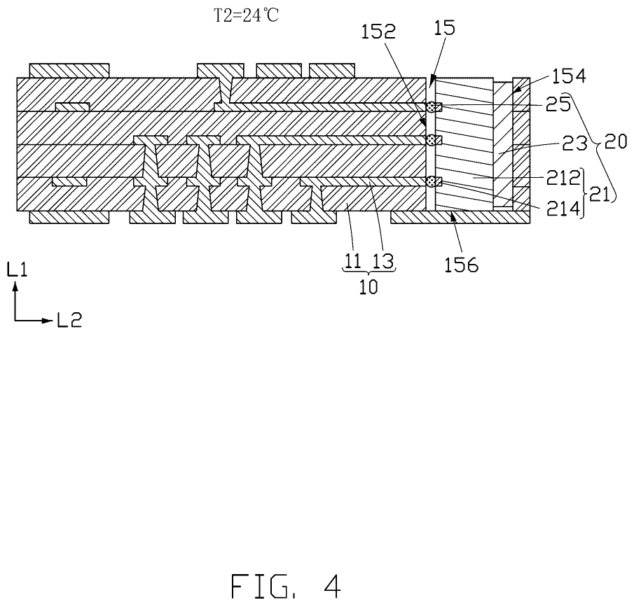

In block 4, referring to FIG. 4, at the second temperature T2, the conductive pastes 25 are in contact with the circuit layer 13, and the deformable member 23 is in contact with the second sidewall 154.

In the embodiment, after the chip assembly 20 is placed in the groove 15, the chip assembly 20 and the circuit board 10 are placed at the second temperature T2 of 24 degrees, and the deformable member 23 returns to the original size. At the same time, both sides of the chip assembly 20 are connected to the circuit board 10. That is, the conductive pastes 25 are in contact with the circuit layer 13, and the deformable member 23 is in contact with the second sidewall 154. Thus, the movement of the chip assembly 20 in the groove 15 after the conductive pastes 25 correspond to the circuit layer 13.

If the chip assembly 20 is not placed at the first temperature T1 but directly placed in the groove 15, it is difficult to adjust the position of the chip assembly 20 in the groove 15, and it is difficult to ensure that the position of the conductive pastes 25 corresponds to the position of the circuit layer 13. Also, in the soldering processes, poor soldering phenomena such as bridging and cracks may occur. If the width of the groove 15 along the second direction L2 is increased, the chip assembly 20 is easily deviated in the groove 15. Even if the conductive pastes 25 are pre-positioned corresponding to the circuit layer 13, in the subsequent manufacturing processes, the chip assembly 20 is easily deviated in the groove 15, and there may be a deviation in the position of the conductive pastes 25 and the circuit layer 13, resulting in poor soldering.

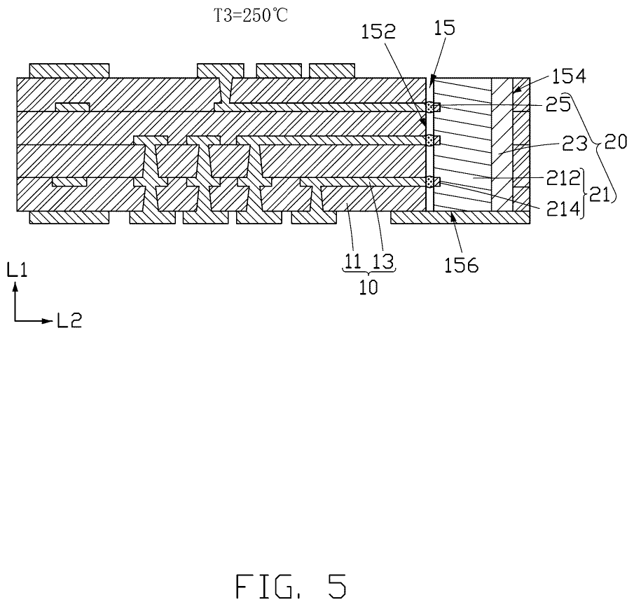

In block 5, referring to FIG. 5, the circuit board 10 and the chip assembly 20 are placed at a third temperature T3 for reflow soldering to electrically connect the conductive pastes 25 and the circuit layer 13. The third temperature T3 is greater than the second temperature T2.

The third temperature T3 can be adjusted according to a type of the conductive pastes 25. For example, in some embodiments, the third temperature T3 can be greater than 220 degrees. In the embodiment, the third temperature T3 is 250 degrees.

At the third temperature T3, the deformable member 23 and the circuit board 10 expand under heat. Since the thermal expansion coefficient of the deformable member 23 is greater than the thermal expansion coefficient of the circuit board 10, the deformable member 23 expands more than the circuit board 10. That is, along the second direction L2, the width of the groove 15 is less than the width of the chip assembly 20. After expansion, the deformable member 23 may push components disposed on both sides of the deformable member 23. That is, the deformable member 23 may push the chip 21 towards the first sidewall 152. At the same time, the conductive pastes 25 are in a molten state at the third temperature T3 and connected to the circuit layer 13. The pushing force of the deformable member 23 ensures a tight connection between the conductive pastes 25 and the circuit layer 13. By using the conductive pastes 25 to directly connect the solder pads 214 and the circuit layer 13, hole drilling and plating processes are omitted.

Referring to FIGS. 4 and 5, when the chip assembly 20 is placed at the second temperature T2, along the first direction L1, the width of the deformable member 23 is smaller than a width of the body 212, and a projection of the deformable member 23 is disposed within a projection of the body 212. Thus, when the chip assembly 20 is placed at the third temperature T3, the deformable member 23 expands, which can avoid the movement of the chip assembly 20 along the first direction L1 due to excessive deformation of the deformable member 23 along the first direction L1, thereby avoiding misalignment between the conductive pastes 25 and the circuit layer 13.

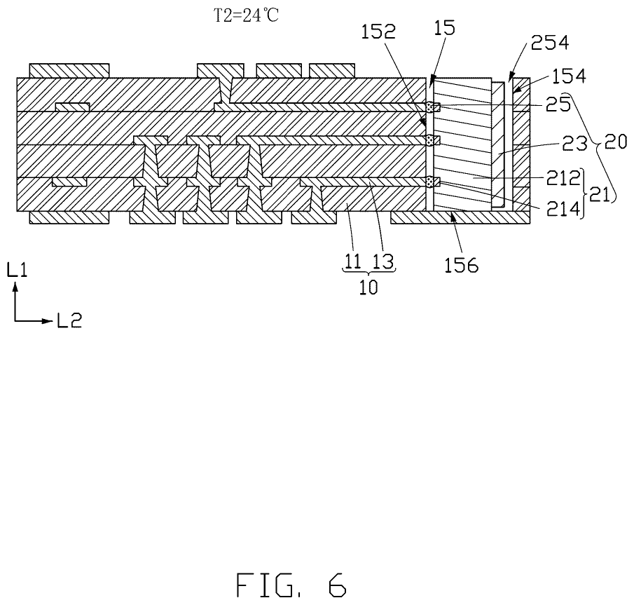

Referring to FIG. 6, when the temperature decreases such as back to the second temperature T2, the conductive pastes 25 becomes a solid state and electrically connects the chip 21 and the circuit board 10. The position of the chip assembly 20 is closer to the first sidewall 152 relative to the position of the chip assembly 20 before reflow soldering. The deformable member 23 contracts and is spaced apart from the second sidewall 154, that is, a second gap 254 is formed between the deformable member 23 and the second sidewall 154. After the reflow soldering process, the chip assembly 20 moves towards the first sidewall 152, so that a width of the second gap 254 is greater than the width of the first gap 252 along the second direction L2.

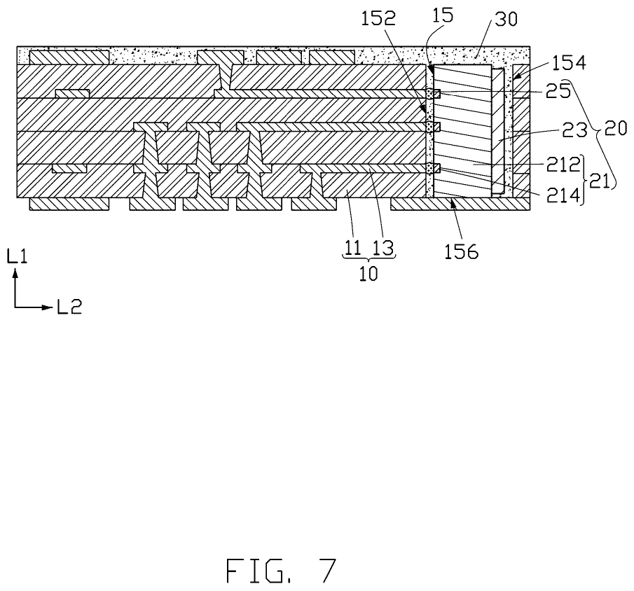

In block 6, referring to FIG. 7, an encapsulating layer 30 is filled in the groove 15.

The encapsulating layer 30 can be filled between the conductive pastes 25 and the first sidewall 152, as well as between the deformable member 23 and the second sidewall 154. The encapsulating layer 30 can further be disposed on a surface of the circuit board 10 where the groove 15 is defined.

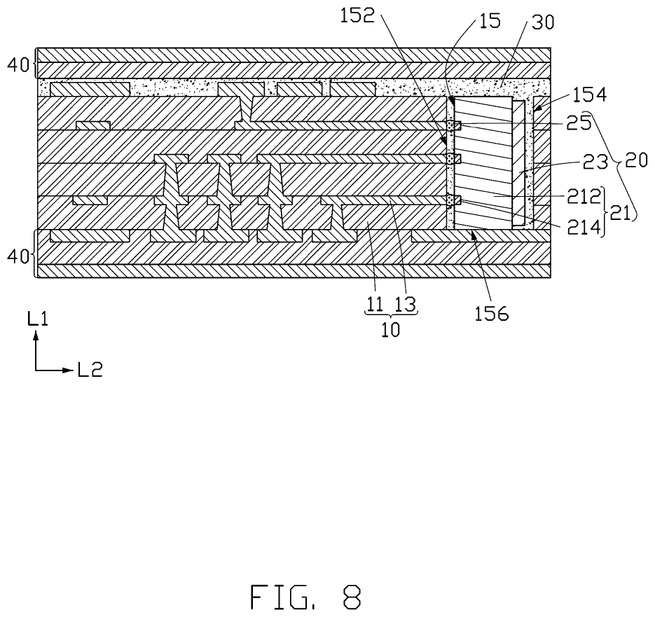

In block 7, referring to FIG. 8, a copper-clad laminate 40 is disposed on a surface of the encapsulating layer 30 away from the circuit board 10.

In some embodiments, a build-up process may further be used to fabricate the more circuit layers on the circuit layer 13. For example, the copper-clad laminate 40 is subsequently used to fabricate a circuit substrate 41, thereby adding more circuit layers on the circuit layer 13. In some embodiments, block 7 can also be omitted.

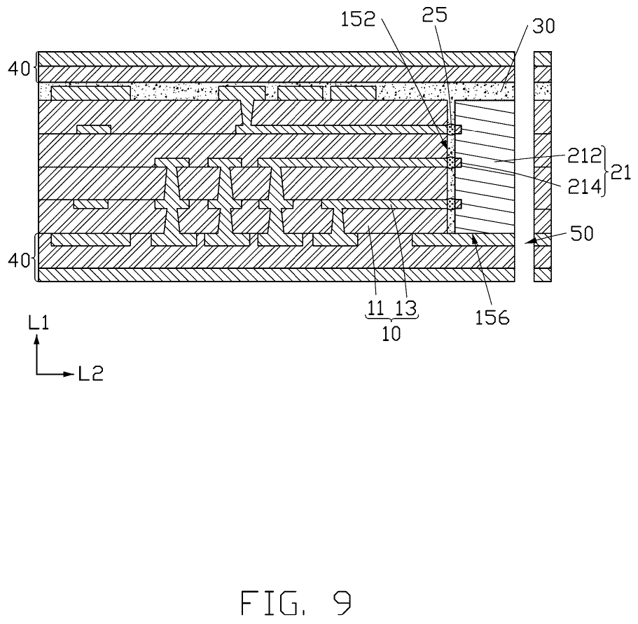

In block 8, referring to FIGS. 9, 10, and 11, a through hole 50 is defined on the copper-clad laminate 40 and the circuit board 10, and the deformable member 23 is removed. A surface of the chip 21 away from the conductive pastes 25 is exposed from the through hole 50, and a conducting layer 51 is formed in the through hole 50.

The conducting layer 51 can be formed in the through hole 50 by electroplating to obtain a chip packaging structure 100. The conducting layer 51 is connected to the surface of the chip 21 for heat dissipation. The conducting layer 51 can further be connected to the circuit board 10 and the circuit layer 13 in the circuit substrate 41 for electrical conduction.

An entire surface of the body 212 away from the solder pads 214 can be connected to the conducting layer 51, thereby increasing a heat dissipation area and thus enhancing the heat dissipation effect.

The chip 21 is packaged in the circuit board 10 with the solder pads 214 facing the second direction L2. Thus, a width of the chip packaging structure 100 along the second direction L2 can be reduced, thereby enabling that the chip packaging structure 100 can be suitable installed in a space with a limited dimension along the second direction L2.

During the formation of the conducting layer 51, the copper-clad laminate 40 is also subjected to circuit fabrication to form the circuit substrate 41.

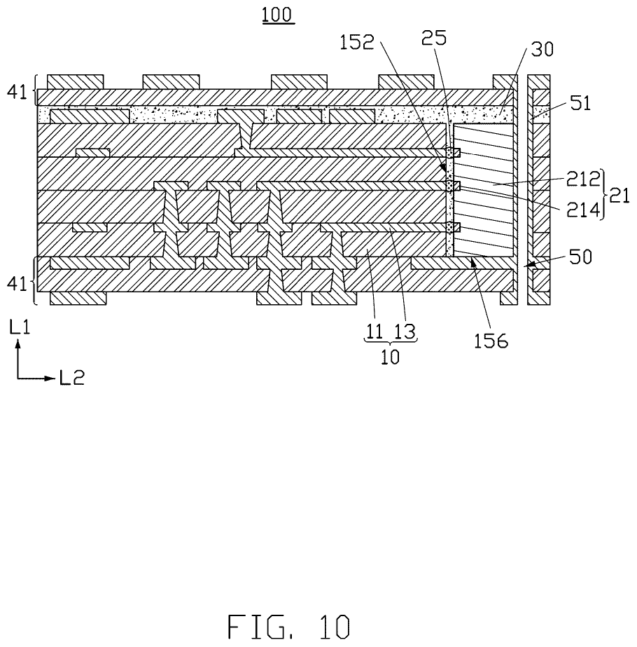

Referring to FIG. 10, the chip packaging structure 100 is provided according to an embodiment of the present disclosure. The chip packaging structure 100 can include the circuit board 10, the chip 21, the conductive pastes 25, and the encapsulating layer 30. The conductive pastes 25 is connected the chip 21 and the circuit board 10, and the encapsulating layer 30 encapsulates the chip 21 in the circuit board 10.

The circuit board 10 includes at least one dielectric layer 11 and at least one circuit layer 13, which are stacked along a first direction L1. The chip 21 includes the body 212 and the solder pads 214 disposed on the surface of the body 212 along the second direction L2. The conductive pastes 25 are disposed between the circuit layer 13 and the solder pads 214 along the second direction L2 to electrically connect the solder pads 214 and the circuit layer 13. The first direction L1 and the second direction L2 can be perpendicular to each other. The encapsulating layer 30 is filled between the chip 21 and the circuit board 10.

The circuit board 10 further includes the conducting layer 51. The through hole 50 extends through the circuit board 10 along the first direction L1, and the conducting layer 51 is connected to the surface of the body 212 away from the solder pads 214. The conducting layer 51 can quickly transfer the heat generated by the chip 21 during operation.

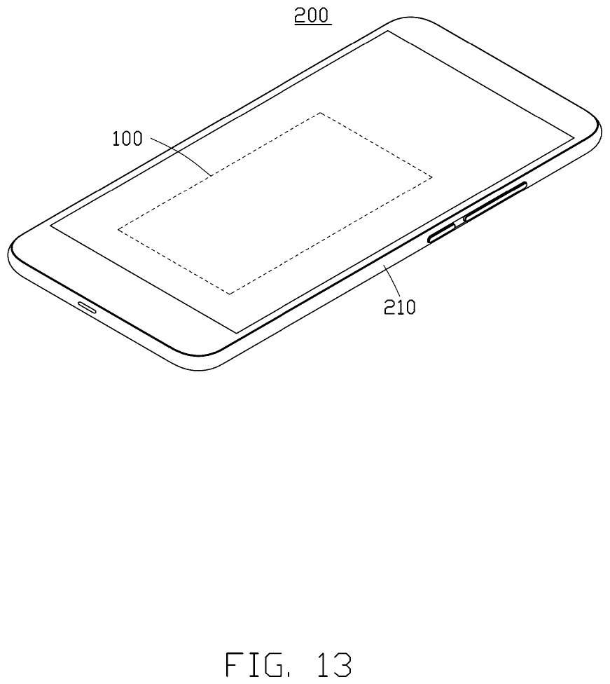

Referring to FIG. 13, a terminal device 200 is provided according to an embodiment of the present disclosure. The terminal device 200 includes the chip packaging structure 100 and a housing 210. The chip packaging structure 100 is disposed in the housing 210. The terminal device 200 can be a mobile phone, a camera, a drone, a computer, a webcam, or the like. In the embodiment, the terminal device 200 is a mobile phone.

The chip packaging method provided by the embodiment of the present disclosure employs a principle of thermal expansion and contraction. Firstly, the chip assembly 20 is placed in an environment at a low-temperature (the first temperature T1) to cause the deformable member 23 within the chip assembly 20 to contract. Then, the chip assembly 20 is placed in the circuit board 10 with the groove 15. In an environment at room temperature (the second temperature T2), the position of the chip assembly 20 within the groove 15 is adjusted so that the solder pads 214 of the chip 21 can correspond to the circuit layer 13 of the circuit board 10, thereby fixing the position of the chip assembly 20 within the groove 15. Reflow soldering is then performed at a high-temperature (the third temperature T3) to connect the conductive pastes 25 to the circuit board 10 and the chip 21. At the high-temperature, the deformable member 23 expands and presses against the chip 21, thereby enhancing the connection reliability between the chip 21 and the circuit board 10.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A method of packaging a chip, the method comprising:
forming a groove on a circuit board, the groove comprising a first sidewall and a second sidewall opposite the first sidewall, the circuit board comprising a circuit layer, the circuit layer exposed from the first sidewall;
providing a chip assembly, the chip assembly comprising the chip, conductive pastes, and a deformable member, the deformable member and the conductive pastes disposed on opposite surfaces of the chip;
placing the chip assembly at a first temperature to cause the deformable member to contract;
placing the chip assembly in the groove, such that the contacted deformable member be spaced apart from the second sidewall;
heating the chip assembly at a second temperature until the conductive pastes being in contact with the circuit layer, and the deformable member being in contact with the second sidewall; and
electrically connecting the conductive pastes to the circuit layer by reflow soldering the circuit board and the chip assembly at a third temperature;
wherein the third temperature is greater than the second temperature, and the second temperature is greater than the first temperature.

2. The method of claim 1, further comprising:
filling an encapsulating layer in the groove;
defining a through hole on the circuit board, removing the deformable member, thereby causing a surface of the chip away from the conductive pastes to be exposed from the through hole; and
forming a conducting layer in the through hole.

3. The method of claim 1, wherein a thermal expansion coefficient of the deformable member is greater than a thermal expansion coefficient of the circuit board.

4. The method of claim 3, wherein a material of the deformable member is selected from one of zinc, copper, lead, and aluminum.

5. The method of claim 2, wherein a thermal expansion coefficient of the deformable member is greater than a thermal expansion coefficient of the circuit board.

6. The method of claim 5, wherein a material of the deformable member is selected from one of zinc, copper, lead, and aluminum.

7. The method of claim 1, wherein the groove is formed by recessing on the circuit board along a first direction, and the chip assembly is further provided by disposing the conductive pastes, the chip, and the deformable member along a second direction which is perpendicular to the first direction.

8. The method of claim 2, wherein the groove is formed by recessing on the circuit board along a first direction, and the chip assembly is further provided by disposing the conductive pastes, the chip, and the deformable member along a second direction which is perpendicular to the first direction.

9. The method of claim 1, wherein the chip assembly is placed in the groove by maintaining a distance between the deformable member and the second sidewall to be greater than or equal to 0.56 um.

10. The method of claim 2, wherein the chip assembly is placed in the groove by maintaining a distance between the deformable member and the second sidewall to be greater than or equal to 0.56 um.

11. The method of claim 1, wherein the first temperature is less than or equal to 0 Celsius, and/or the third temperature is greater than 220 Celsius.

12. The method of claim 2, wherein the first temperature is less than or equal to 0 Celsius, and/or the third temperature is greater than 220 Celsius.

13. A chip packaging structure comprising:
a circuit board comprising a dielectric layer and a circuit layer stacked along a first direction;
a chip comprising a body and solder pads disposed on the body along a second direction;
conductive pastes disposed between the circuit layer and the solder pads along the second direction, the conductive pastes electrically connected to the solder pads and the circuit layer; and
a conducting layer extending through the circuit board along the first direction and connected to a surface of the body of the chip away from the solder pads.

14. The chip packaging structure of claim 13, wherein the circuit layer, the solder pads, and the chip are disposed along the second direction.

15. The chip packaging structure of claim 13, wherein the first direction and the second direction are perpendicular to each other.

16. The chip packaging structure of claim 15, wherein the first direction and the second direction are perpendicular to each other.

17. A terminal device comprising:
a chip packaging structure comprising
a circuit board comprising a dielectric layer and a circuit layer stacked along a first direction;
a chip comprising a body and solder pads disposed on the body along a second direction;
conductive pastes disposed between the circuit layer and the solder pads along the second direction, the conductive pastes electrically connected to the solder pads and the circuit layer; and
a conducting layer extending through the circuit board along the first direction and connected to a surface of the body of the chip away from the solder pads; and
a housing accommodating the chip packaging structure.

18. The terminal device of claim 17, wherein the circuit layer, the solder pads, and the chip are disposed along the second direction.

19. The terminal device of claim 17, wherein the first direction and the second direction are perpendicular to each other.

20. The terminal device of claim 19, wherein the first direction and the second direction are perpendicular to each other.
